(19) United States
(12) Patent Application Publication
(10) Pub. No.: US 2019/0074181 A1
(43) Pub. Date: Mar. 7, 2019

(54) TEMPLATE AND TEMPLATE MANUFACTURING METHOD

(71) Applicant: Toshiba Memory Corporation, Minato-ku (JP)

(72) Inventors: Yusaku Izawa, Yokkaichi (JP); Masaki Mae, Yokkaichi (JP)

(73) Assignee: Toshiba Memory Corporation, Minato-ku (JP)

(21) Appl. No.: 15/903,252

(22) Filed: Feb. 23, 2018

(30) Foreign Application Priority Data
Sep. 5, 2017 (JP) 2017-170316

(51) Int. Cl. H01L 21/033; G06F 17/50

(52) U.S. Cl. CPC H01L 21/0337; G06F 2217/12; G06F 17/50

(57) ABSTRACT

According to one embodiment, a template includes a first stepwise structure that includes first level differences and first terraces provided between the first level differences adjacent to each other. The first level differences are a first to an N-th (N is an integer of 3 or more) provided while being shifted in a first direction. Each of the first terraces includes a second stepwise structure that includes second level differences and second terraces provided between the second level differences adjacent to each other. The second level differences are a first to an M-th (M is an integer of 2 or more) provided while being shifted in a second direction perpendicular to the first direction. In the second terraces in each of the first terraces, as a portion dug in the template is deeper, the portion has a larger length in the second direction.

### CROSS-REFERENCE TO RELATED APPLICATIONS

This application is based upon and claims the benefit of priority from Japanese Patent Application No. 2017-170316, filed on Sep. 5, 2017; the entire contents of which are incorporated herein by reference.

### FIELD

Embodiments described herein relate generally to a template and a template manufacturing method.

### BACKGROUND

In order to fabricate a stepwise wiring line structure in a three-dimensional memory, a method is known in which a stepwise resist is formed above a substrate by using an imprint technique and a processing object is three-dimensionally processed by using the stepwise resist as a mask. Where this method is used, the number of patterning operations necessary for the process is remarkably reduced, and devices can be manufactured with a lower cost, as compared with a method in which resist patterning and etching are repeated for respective steps.

However, in the method using a stepwise resist, a processing object is etched through the resist having a three-dimensional shape with recessed and projected portions, and thus is more affected by side etching, as compared with etching through a flat resist coating film. Accordingly, even if etching is performed by using a stepwise resist having a layout the same as a desired shape above a processing object, the desired shape can be hardly obtained and positional deviation is caused on the step terraces, because of an influence of side etching. If such positional deviation is caused on the step terraces, suitable connections can be hardly formed when contact vias are set down onto the step terraces thereafter, and the devices may become unable to operate normally.

### BRIEF DESCRIPTION OF THE DRAWINGS

FIG. 1 is a partial sectional view schematically illustrating a configuration example of a template according to a comparative example;

FIGS. 2A to 2E are sectional views schematically illustrating an example of procedures for forming a stepwise structure to a processing object, by using a stepwise resist pattern according to the comparative example;

FIG. 3 is a partial sectional view schematically illustrating a configuration example of a template according to a first embodiment;

FIGS. 4A to 4D are sectional views schematically illustrating an example of procedures for forming a stepwise structure to a processing object, by using a stepwise resist pattern according to the first embodiment;

FIG. 5 is a diagram schematically illustrating an example of a resist pattern structure including stepwise structures in two directions orthogonal to each other;

FIG. 6 is a top view schematically illustrating a configuration example of a stepwise resist pattern subjected to shape correction according to a second embodiment;

FIG. 7 is a partial bottom view schematically illustrating a configuration example of a template according to the second embodiment;

FIGS. 8A and 8B are sectional views schematically illustrating an example of a change in the shape of a resist pattern between before and after an etching process according to a comparative example;

FIGS. 9A and 9B are partial sectional views schematically illustrating configuration examples of a template according to a third embodiment;

FIGS. 10A to 10C are sectional views illustrating examples of a change in the shape of a resist pattern between before and after an etching process, where the resist pattern is formed by the template of each of FIGS. 9A and 9B;

FIG. 11 is a sectional view schematically illustrating another example of a change in the shape of a resist pattern between before and after an etching process according to a comparative example;

FIGS. 12A and 12B are partial sectional views schematically illustrating configuration examples of a template according to the third embodiment;

FIGS. 13A and 13B are sectional views illustrating examples of a change in the shape of a resist pattern between before and after an etching process, where the resist pattern is formed by the template of each of FIGS. 12A and 12B;

FIGS. 14A and 14B are top views schematically illustrating an example of a change in the shape of a resist pattern between before and after an etching process according to a comparative example;

FIG. 15 is a partial top view schematically illustrating a configuration example of a template according to the third embodiment;

FIGS. 16A and 16B are top views illustrating an example of a change in the shape of a resist pattern between before and after an etching process, where the resist pattern is formed by the template of FIG. 15;

FIG. 17 is a top view schematically illustrating another example of a change in the shape of a resist pattern between before and after an etching process according to a comparative example;

FIG. 18 is a partial top view schematically illustrating another configuration example of a template according to the third embodiment;

FIG. 19 is a top view illustrating another example of a change in the shape of a resist pattern between before and after an etching process, where the resist pattern is formed by the template of FIG. 18;

FIG. 20 is a flowchart illustrating an example of the sequence of a template manufacturing method according to a fourth embodiment;

FIG. 21 is a flowchart illustrating an example of the process sequence of a data registration method into three-dimensional shape correction information; and

FIG. 22 is a block diagram schematically illustrating a hardware configuration example of an information processing device configured to execute the processes illustrated in FIGS. 20 and 21.

### DETAILED DESCRIPTION

According to one embodiment, a template includes a first stepwise structure that includes a plurality of first level differences and a plurality of first terraces provided between the first level differences adjacent to each other. The plurality of first level differences are a first to an N-th (N is an integer of 3 or more) provided while being shifted in a first direction. Each of the first terraces includes a second stepwise structure that includes a plurality of second level differences and a plurality of second terraces provided between the second level differences adjacent to each other. The plurality of second level differences are a first to an M-th (M is an integer of 2 or more) provided while being shifted in a second direction perpendicular to the first direction. In the plurality of second terraces in each of the first terraces, as a portion dug in the template is deeper, the portion has a larger length in the second direction.

Exemplary embodiments of a template and a template manufacturing method will be explained below in detail with reference to the accompanying drawings. The present invention is not limited to the following embodiments.

### First Embodiment

In the first embodiment, an explanation will be given of a template manufacturing method in a case where a stepwise structure, in which level differences are provided in the height direction while being shifted in a first direction, is to be formed in a processing object.

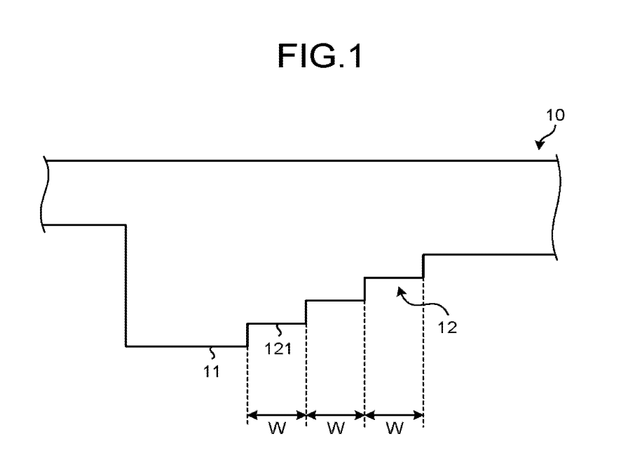

FIG. 1 is a partial sectional view schematically illustrating a configuration example of a template according to a comparative example. The template 10 according to the comparative example includes a pattern formation face 11 provided with a stepwise pattern 12 that has the same in size and shape as a pattern desired to be formed on a processing object. Here, where a stepwise structure including terraces each having a width W is to be formed on the processing object, the stepwise pattern 12 comes to include terraces 121 each having the width W. In other words, in the stepwise pattern 12 according to the comparative example, no consideration has been given to side etching on a resist pattern caused during etching.

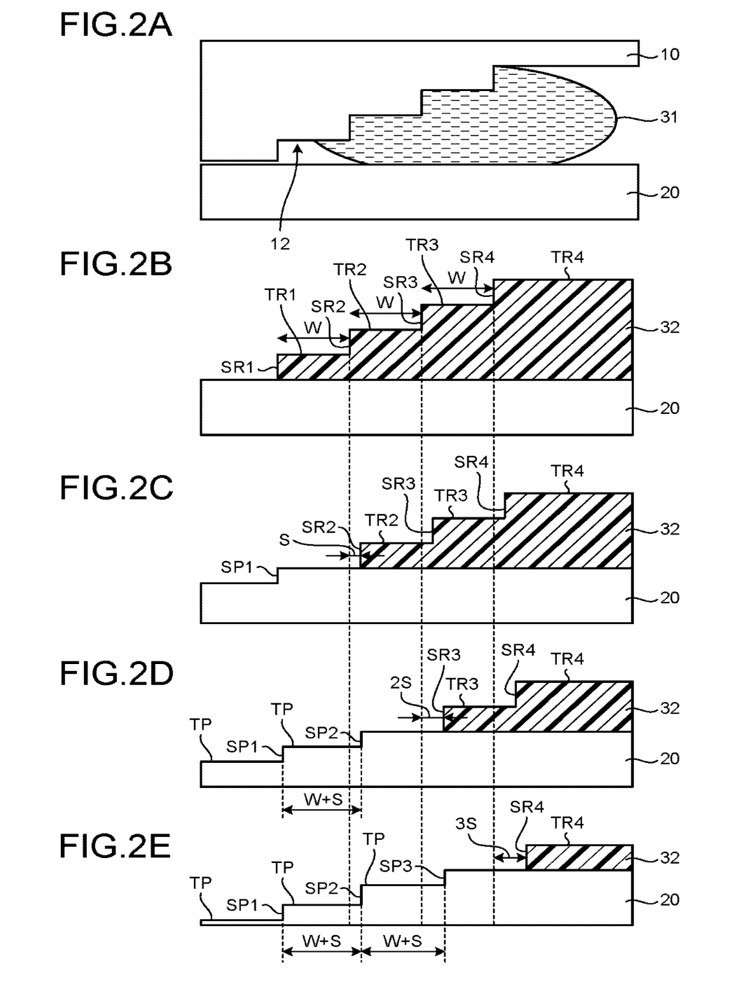

FIGS. 2A to 2E are sectional views schematically illustrating an example of procedures for forming a stepwise structure to a processing object, by using a stepwise resist pattern according to the comparative example. First, a resist is applied onto the processing object. In this case, for example, the processing object is a stacked body formed above a semiconductor substrate by alternately stacking a first insulating film and a second insulating film each as a plurality of layers. The first insulating film is formed of, for example, a silicon oxide film, and a second insulating film is formed of, for example, a silicon nitride film. Then, as illustrated in FIG. 2A, the template 10 formed with the stepwise pattern 12 is set in contact with the resist 31, so that the recessed portions of the pattern formation face of the template 10 are filled with the resist 31.

Thereafter, the template 10 is separated from a resist pattern 32, and, as illustrated in FIG. 2B, a stepwise resist pattern 32 is formed on the processing object 20. In this resist pattern 32, it is assumed that the terraces present from the lowermost terrace to the uppermost terrace will be referred to as “first terrace” TR1, “second terrace” TR2, “third terrace” TR3, and “fourth terrace” TR4 in order, and that the level differences present from the lowermost level difference to the uppermost level difference will be referred to as “first level difference” SR1, “second level difference” SR2, “third level difference” SR3, and “fourth level difference” SR4 in order. Here, the width W of each terrace of the resist pattern 32 is equal to the width of each terrace of the stepwise structure expected to be formed on the processing object 20. Specifically, in the case of the template 10 according to the comparative example, no consideration has been given to side etching on the resist pattern 32, and thus the resist pattern 32 is formed such that the width W of each terrace is equal to the width W of each terrace of the stepwise structure to be formed on the processing object 20.

Then, as illustrated in FIG. 2C, the processing object 20 is etched, through the resist pattern 32 serving as a mask, by using dry etching, such as a Reactive Ion Etching (RIE) method. FIG. 2C illustrates a state where the first terrace TR1 of the resist pattern 32 has disappeared. Specifically, in the state of FIG. 2B, the region not covered with the resist pattern 32 is etched, and a level difference SP1 of one step is formed on the processing object 20. The position of this level difference SP1 corresponds to the position of the first level difference SR1 of the resist pattern 32.

Thereafter, as illustrated in FIG. 2D, the processing object 20 is further etched. FIG. 2D illustrates a state where the second terrace TR2 of the resist pattern 32 has disappeared. Specifically, in the state of FIG. 2C, the region not covered with the resist pattern 32 is etched. Further, part of the processing object 20 already etched is also etched, so that level differences SP1 and SP2 of two steps are formed on the processing object 20.

Similarly, as illustrated in FIG. 2E, the processing object 20 is further etched. FIG. 2E illustrates a state where the third terrace TR3 of the resist pattern 32 has disappeared. Specifically, in the state of FIG. 2D, the region not covered with the resist pattern 32 is etched. Further, part of the processing object 20 already etched is also etched, so that level differences SP1, SP2, and SP3 of three steps are formed on the processing object 20.

In the comparative example, no consideration has been given to side etching on the resist pattern 32. Accordingly, at the time point when the resist pattern 32 is formed as illustrated in FIG. 2B, the positions of the respective level differences SR1 to SR4 agree to the positions of the level differences desired to be formed on the processing object 20. On the other hand, in etching, as the layer of the resist pattern 32 is present more on the upper side, the etching time of the layer becomes longer. Further, etching is developed not only in the height direction, but also in a lateral direction. Accordingly, for example, when the first terrace TR1 disappears for the time from FIG. 2B to FIG. 2C, the position of the second level difference SR2 retreats in a direction toward the thicker part of the resist pattern 32. The difference between the position of the second level difference SR2 in the state of FIG. 2B and the position of the second level difference SR2 in the state of FIG. 2C is expressed by a side etching amount S. Further, the positions of the third level difference SR3 and the fourth level difference SR4 also retreat by the side etching amount S, in substantially the same way.

Similarly, at the time point when the second terrace TR2 has disappeared, the positions of the third level difference SR3 and the fourth level difference SR4 have retreated each by 2S from the positions of the third level difference SR3 and the fourth level difference SR4 in the state of FIG. 2B. Specifically, at the time point of FIG. 2D, the side etching amount becomes 2S. At the time point when the third terrace TR3 has disappeared, the position of the fourth level difference SR4 has retreated by 3S from the position of the fourth level difference SR4 in the state of FIG. 2B. Thus, at the time point of FIG. 2E, the side etching amount becomes 3S.

As described above, side etching is caused on the resist pattern during etching, and the width of each terrace TP to be formed on the processing object 20 becomes “W+S”, which is larger than the desired terrace size W. Accordingly, where the template 10 is used that is designed to form a resist pattern that has the same in size and shape as the stepwise structure to be formed on the processing object 20, the desired pattern cannot be formed on the processing object 20.

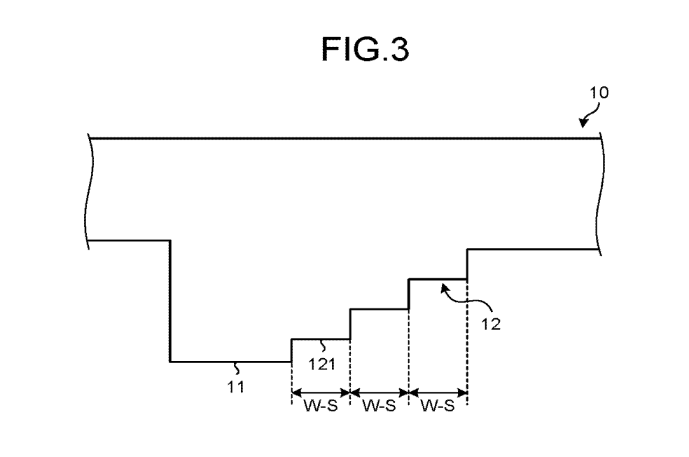

In consideration of the above, in the first embodiment, correction is performed to the stepwise pattern 12 of the template 10, on the basis of a side etching amount on the resist pattern caused during an etching process. FIG. 3 is a partial sectional view schematically illustrating a configuration example of a template according to the first embodiment. In the template 10 according to the first embodiment, the shape of the stepwise pattern 12 is basically the same as the shape of the stepwise pattern 12 of the template 10 illustrated in FIG. 1 according to the comparative example. However, there is a difference from FIG. 1, such that the width of the terrace 121 at each step is set to “W-S”, in consideration of side etching on the resist pattern caused during the etching process. Here, the constituent elements corresponding to those illustrated in FIG. 1 are denoted by the same reference symbols, and their description will be omitted.

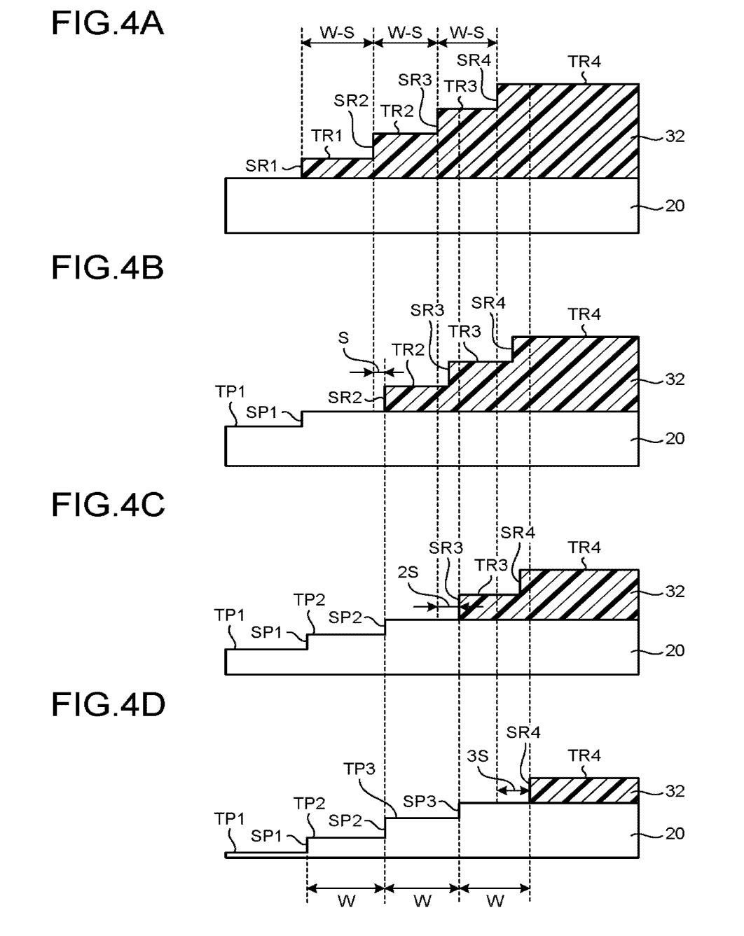

FIGS. 4A to 4D are sectional views schematically illustrating an example of procedures for forming a stepwise structure to a processing object, by using a stepwise resist pattern according to the first embodiment. First, the template 10 formed with the stepwise pattern illustrated in FIG. 3 is set in contact with a resist applied onto the processing object, and the resist is cured. For example, the processing object is a stacked body formed above a semiconductor substrate by alternately stacking the first insulating film and the second insulating film each as a plurality of layers.

Then, the template 10 is separated from the resist, so that, as illustrated in FIG. 4A, a stepwise resist pattern 32 is formed on the processing object 20. The width of each terrace of the resist pattern 32 becomes “W-S”. Here, the region not covered with the resist pattern 32 is a region corresponding to the first terrace TP1 to be formed on the processing object 20.

Thereafter, as illustrated in FIG. 4B, the processing object 20 is etched, through the resist pattern 32 serving as a mask, by using dry etching, such as the RIE method. FIG. 4B illustrates a state where the first terrace TR1 of the resist pattern 32 has disappeared. Specifically, in the state of FIG. 4A, the region not covered with the resist pattern 32 is etched, and a level difference SP1 of one step is formed on the processing object. The region formed with this level difference SP1 is to be the first terrace TP1. The position of the first level difference SP1 formed on the processing object 20 is the same as the position of the first level difference SR1 of the resist pattern 32 of FIG. 4A. Further, during the etching process, the resist pattern 32 undergoes side etching, and the positions of the second level difference SR2, the third level difference SR3, and the fourth level difference SR4 retreat each by S from the state of FIG. 4A. The region on the processing object 20 exposed by disappearance of the first terrace TR1 of the resist pattern 32 is a region to be the second terrace TP2. The width of the second terrace TP2, i.e., the distance between the position of the first level difference SP1 of the processing object 20 and the position of the second level difference SR2 of the resist pattern 32, becomes W because of side etching on the resist pattern 32.

Then, as illustrated in FIG. 4C, the processing object 20 is further etched. FIG. 4C illustrates a state where the second terrace TR2 of the resist pattern 32 has disappeared. Specifically, in the state of FIG. 4B, the region not covered with the resist pattern 32 is etched. Further, part of the processing object 20 already etched is also etched, so that level differences SP1 and SP2 of two steps are formed on the processing object 20. By disappearance of the second terrace TR2, the second terrace TP2 is formed on the processing object 20. Further, during the etching process, the resist pattern 32 also undergoes etching, so that the positions of the third level difference SR3 and the fourth level difference SR4 retreat each by S from the state of FIG. 4B. The region on the processing object 20 exposed by disappearance of the second terrace TR2 of the resist pattern 32 is a region to be the third terrace TP3. The width of the third terrace TP3 becomes W because of side etching on the resist pattern 32.

Similarly, as illustrated in FIG. 4D, the processing object 20 is further etched. FIG. 4D illustrates a state where the third terrace TR3 of the resist pattern 32 has disappeared. Specifically, in the state of FIG. 4C, the region not covered with the resist pattern 32 is etched. Further, part of the processing object 20 already formed with the level differences SP1 and SP2 of two steps is also etched, so that level differences SP1, SP2, and SP3 of three steps are formed on the processing object 20. By disappearance of the third terrace TR3, the third terrace TP3 is formed on the processing object 20. Further, during the etching process, the resist pattern 32 undergoes side etching, so that the positions of the third level difference SR3 and the fourth level difference SR4 retreat each by S from the state of FIG. 4C. The region on the processing object 20 exposed by disappearance of the third terrace TR3 of the resist pattern 32 is a region to be the fourth terrace. The width of the fourth terrace becomes W because of side etching on the resist pattern 32. In this way, a stepwise structure, in which the width of each terrace is W, is formed on the processing object 20.

In the first embodiment, an imprint process is performed by using a template 10 that has been prepared to obtain stepwise data required on a processing object 20, and a stepwise resist pattern 32 is thereby formed on a processing object 20. Then, a difference is obtained between actual three-dimensional shape data of the processing object 20, which has been acquired by performing an etching process using the resist pattern 32 to the processing object 20, and three-dimensional shape data required on the processing object 20. On the basis of a side etching amount in a planar direction of the processing object 20, which is derived from this difference, the template 10 is corrected, and an imprint process is executed by using the corrected template 10. Consequently, the stepwise resist pattern 32 formed by using the corrected template 10 becomes a pattern made in consideration of side etching during the etching process, and thus the stepwise pattern to be formed on the processing object 20 comes to agree with the required shape. In other words, it is possible to reduce shape errors to be generated when the resist pattern 32 is transferred onto the processing object 20. As a result, it is possible to suppress positional deviation of the terraces of a stepwise structure on the processing object 20, and to set down contact vias in the right place on the terraces of the stepwise structure in a subsequent process.

### Second Embodiment

In the first embodiment, an explanation has been given of a case where level differences are provided in the height direction while being shifted in one direction. In the second embodiment, an explanation will be given of a template manufacturing method in a case where a stepwise structure, in which level differences are provided in the height direction while being shifted in a first direction and a second direction, is to be formed in a processing object. Here, as a correction method in the first direction has already described in the first embodiment, its description will be omitted while a correction method in the second direction will be described.

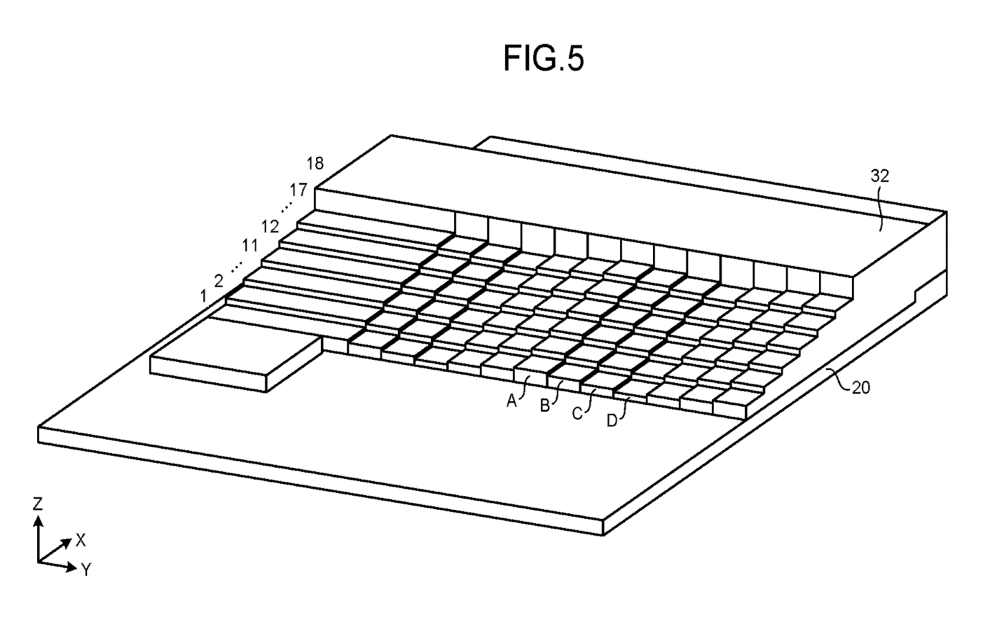

FIG. 5 is a diagram schematically illustrating an example of a resist pattern structure including stepwise structures in two directions orthogonal to each other. Here, the direction in which the step numbers keep monotonously increasing will be referred to as “X-direction”, the height direction will be referred to as “Z-direction”, and the direction perpendicular to the X-direction and the Z-direction will be referred to as “Y-direction”. Here, it is assumed that the resist pattern 32 includes a stepwise structure having 18 steps in the X-direction. However, some of the 18 steps of the stepwise structure are not illustrated. Further, the resist pattern 32 includes a stepwise structure having four steps, i.e., a step A to a step D, in the Y-direction, and the step numbers are periodically changed in the Y-direction. Here, the shape of the resist pattern 32 illustrated in FIG. 5 represents the shape required on the processing object 20, as well.

When an etching process is performed to a processing object by using this resist pattern 32, as the step of the resist pattern 32 is present more on the upper side, the step comes to have a longer time of being exposed to etching, and thus undergoes side etching more, as described in the first embodiment. In the first embodiment, a consideration is given to side etching on level difference portions perpendicular to the X-direction. In the second embodiment, a consideration is given not only to side etching on level difference portions perpendicular to the X-direction, but also to side etching on level difference portions perpendicular to the Y-direction. It is assumed that, while one step of a resist pattern (terrace) having a level difference perpendicular to the X-direction is disappearing, each level difference portion perpendicular to the Y-direction undergoes a side etching amount R. In this case, this side etching amount R is used to correct the shape of the resist pattern 32. Here, the above explanation has been given by referring to level difference portions perpendicular to the Y-direction; however, in general, these portions may be level difference portions perpendicular to any direction other than the X-direction.

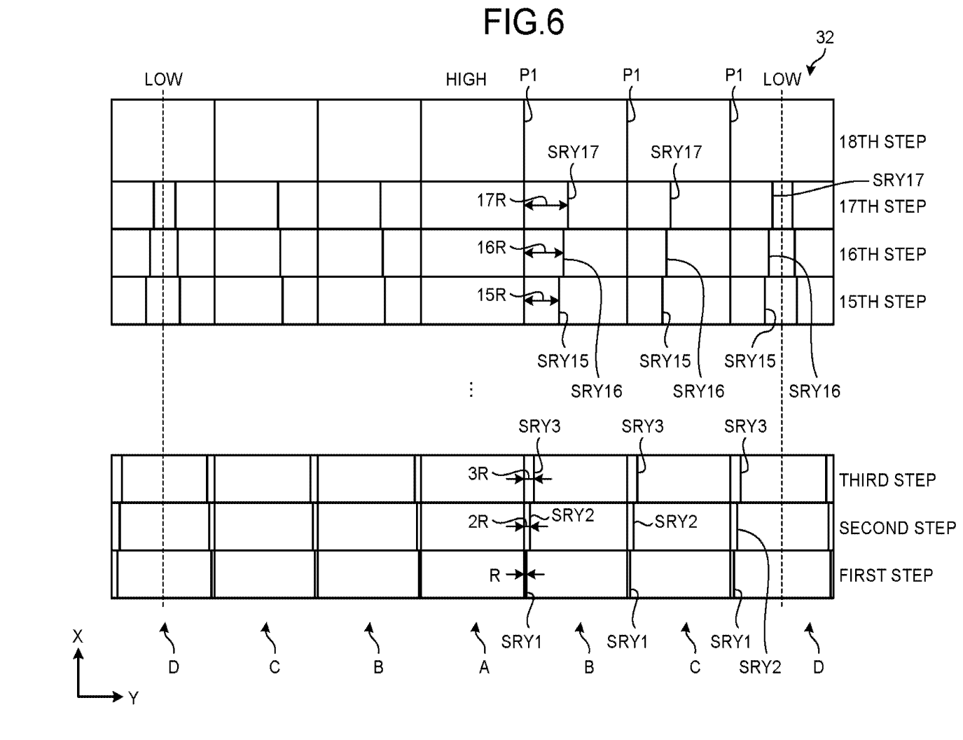

FIG. 6 is a top view schematically illustrating a configuration example of a stepwise resist pattern subjected to shape correction according to the second embodiment. In this resist pattern 32, a first level-difference formation direction is in the X-direction, and a second level-difference formation direction is in the Y-direction. From the lowermost terrace to the uppermost terrace, level differences are provided while being shifted in the X-direction. Further, in the terrace at each step in the X-direction, level differences are provided while being shifted in the Y-direction. Here, each step in the X-direction is provided with the step D, the step C, the step B, and the step A in order from the lowest terrace to the highest terrace.

As illustrated in FIG. 6, in the terrace at the first step in the X-direction, each of the positions of level differences SRY1 perpendicular to the Y-direction of the resist pattern 32 is shifted in a direction toward the thinner part of the resist pattern 32 by R from the position P1 desired to be formed on the processing object 20. Consequently, the level difference positions on the processing object to be formed by an etching process can be at required positions. Similarly, in the terrace at the n-th step (“n” is an integer of 1 or more and 17 or less) in the X-direction, each of the positions of level differences SRYn perpendicular to the Y-direction of the resist pattern 32 is shifted in a direction toward the thinner part of the resist pattern 32 by nR from the position P1 desired to be formed on the processing object 20.

In each step in the X-direction, the height is periodically changed in the manner of “step D→step C→step B→step A→step B→step C→step D . . . ”. As described above, each of the positions of level differences SRYn perpendicular to the Y-direction of the resist pattern 32 is shifted in a direction toward the thinner part of the resist pattern 32. Accordingly, in the terrace at each step in the X-direction, the Y-direction length of the uppermost step A is the largest, the Y-direction lengths of the step B and the step C are almost equal to the Y-direction lengths of the required stepwise structure, and the Y-direction length of the lowermost step D is the smallest. Further, as the step of the resist pattern 32 is present more on the upper side, the shift amount of each of the positions of the level differences SRYn perpendicular to the Y-direction becomes larger. Accordingly, in the step A, as the step is present more on the upper side in the X-direction, the Y-direction length becomes larger. In the step D, as the step is present more on the upper side in the X-direction, the Y-direction length becomes smaller. On the other hand, in each of the step B and the step C, the Y-direction length is the same among the respective steps in the X-direction. Here, the structure is simplified on the premise that no additional etching is present other than side etching.

In a case where correction to a template 10 is made only of a factor relating to side etching, the terrace at the n-th step in the X-direction of the resist pattern 32 is formed as follows: The width of the step A is expressed by “W_{Y}+2nR”, the width of each of the step B and the step C is expressed by W_{Y}, and the width of the step D is expressed by “W_{Y}−2nR”, where W_{Y} denotes the required width of each of the step A to step D in the Y-direction.

When the resist pattern 32 illustrated in FIG. 6 is used to process the processing object 20, the processing object 20 is obtained to include a structure with the resist pattern 32 of FIG. 5 transposed onto the processing object 20.

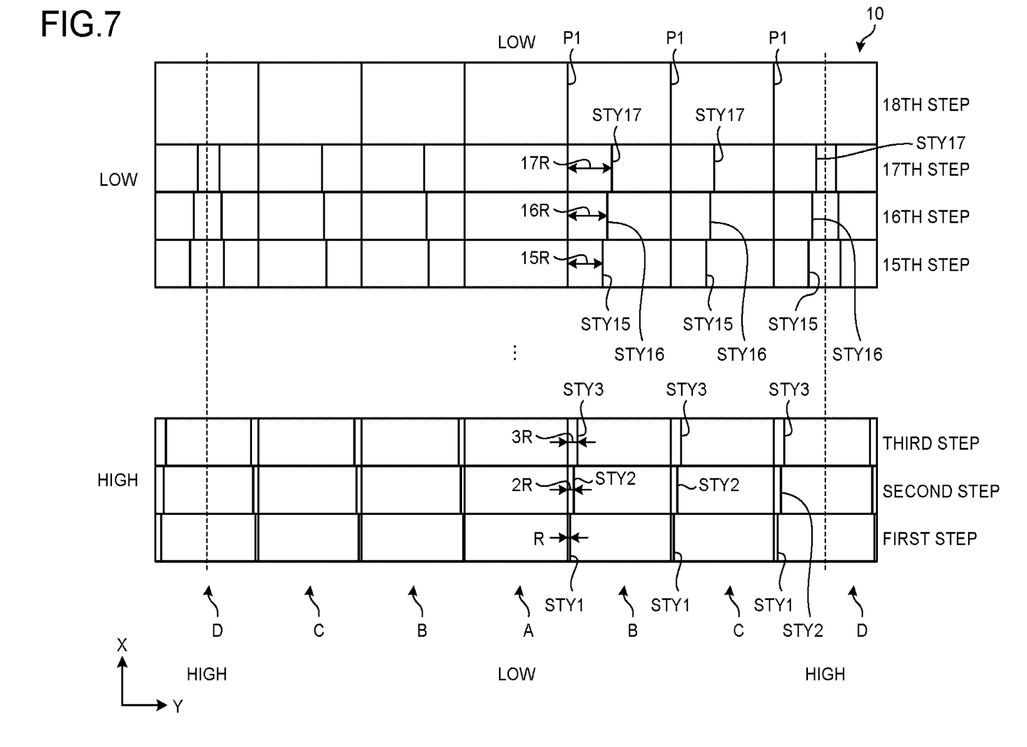

FIG. 7 is a partial bottom view schematically illustrating a configuration example of a template according to the second embodiment. The template 10 includes a structure formed of recessed and projected portions reverse to those of the resist pattern 32 of FIG. 6. In this template 10, a first level-difference formation direction is in the X-direction, and a second level-difference formation direction is in the Y-direction. From the lowermost terrace to the uppermost terrace, level differences are provided while being shifted in the X-direction. Further, in each step in the X-direction, level differences are provided while being shifted in the Y-direction. Here, each step in the X-direction is provided with a step D, a step C, a step B, and a step A in order from the highest terrace to the lowest terrace.

As illustrated in FIG. 7, in the terrace at the first step in the X-direction, each of the positions of level differences STY1 perpendicular to the Y-direction of the pattern of the template 10 is shifted in a direction toward the thicker part of the pattern of the template 10 by R from the position P1 desired to be formed on the processing object 20. Consequently, the level difference positions on the processing object to be formed by an etching process can be at required positions. Similarly, in the terrace at the n-th step in the X-direction, each of the positions of level differences SRYn perpendicular to the Y-direction of the pattern of the template 10 is shifted in a direction toward the thicker part of the pattern of the template 10 by nR from the position P1 desired to be formed on the processing object 20.

In each step in the X-direction, the height is periodically changed in the manner of “step D→step C→step B→step A→step B→step C→step D . . . ”. As described above, each of the positions of level differences STYn perpendicular to the Y-direction of the pattern of the template 10 is shifted in a direction toward the thicker part of the pattern of the template 10. Accordingly, in each step in the X-direction, the Y-direction length of the lowermost step A is the largest, the Y-direction lengths of the step B and the step C are almost equal to the Y-direction lengths of the required stepwise structure, and the Y-direction length of the uppermost step D is the smallest. Further, as the step of the pattern of the template 10 is present more on the lower side, the shift amount of each of the positions of the level differences STYn perpendicular to the Y-direction becomes larger. Accordingly, in the step A, as the step is present more on the lower side in the X-direction, the Y-direction length becomes larger. In the step D, as the step is present more on the lower side in the X-direction, the Y-direction length becomes smaller. On the other hand, in each of the step B and the step C, the Y-direction length is the same among the respective steps in the X-direction.

Here, in FIGS. 6 and 7, the explanation has been given only of the correction in the Y-direction. In the X-direction, the correction explained in the first embodiment can be performed.

Also in the second embodiment, an effect substantially the same as that of the first embodiment can be obtained.

### Third Embodiment

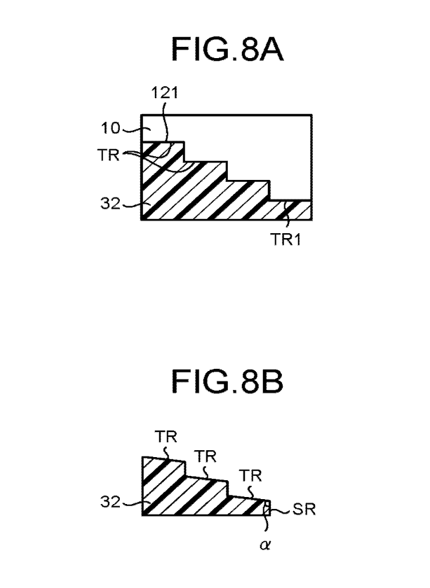

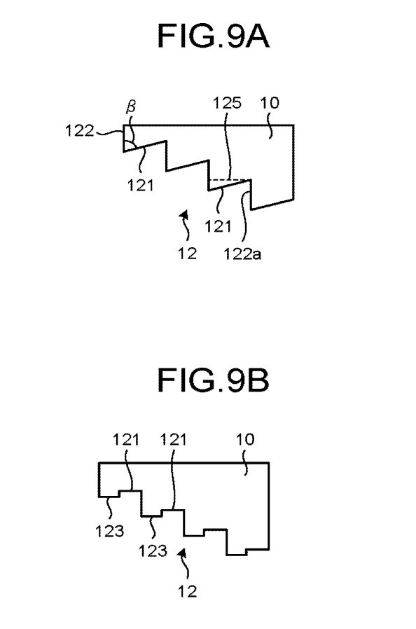

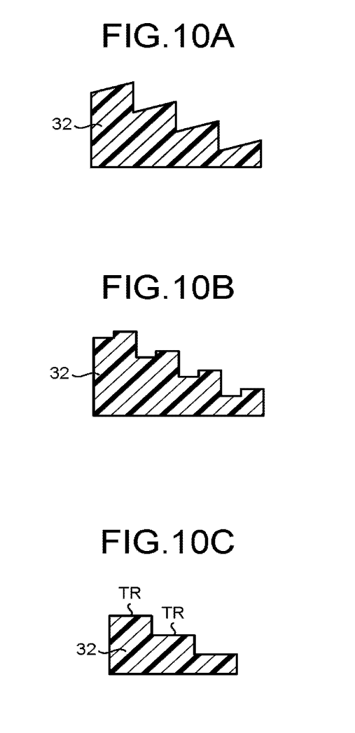

FIGS. 8A and 8B are sectional views schematically illustrating an example of a change in the shape of a resist pattern between before and after an etching process according to a comparative example. FIGS. 9A and 9B are partial sectional views schematically illustrating configuration examples of a template according to a third embodiment. FIGS. 10A to 10C are sectional views illustrating examples of a change in the shape of a resist pattern between before and after an etching process, where the resist pattern is formed by the template of each of FIGS. 9A and 9B.

As illustrated in FIG. 8A, when a template 10 including a stepwise structure with horizontal terraces 121 is used to cure a resist, a stepwise resist pattern 32 including horizontal terraces TR is obtained. This resist pattern 32 is used as a mask to etch a processing object. As illustrated in FIG. 8B, there is a case where the terrace TR at each step of the resist pattern 32 comes to have a tapered shape, when the terrace TR1 at the first step has disappeared. Specifically, there is a case where each step has a shape such that the angle α formed between the terrace TR and the level difference SR becomes an obtuse angle. For example, this shape is generated because etched part of the resist pattern 32 is re-deposited on the terraces TR of the resist pattern 32.

In consideration of the above, an etching amount is calculated that is caused by etching at the position of each terrace TR while the terrace TR of one step is disappearing, and the calculated amount is used to correct the shape of the template 10. For example, as illustrated in FIG. 9A, the stepwise pattern 12 of the template 10 is prepared such that the angle β formed between the terrace 121 and the level difference 122 becomes an acute angle. Here, in each terrace 121 of the template 10, the difference in the Z-direction between this terrace 121 and a horizontal plane 125 passing through the upper end of the one step-lower level difference 122a is determined on the basis of an etching amount at the position of each terrace TR of the resist pattern 32 illustrated in FIGS. 8A and 8B. Further, the stepwise pattern 12 of the template 10 illustrated in FIG. 9A can be formed by adjusting etching conditions. FIG. 10A illustrates a resist pattern 32 formed by using the template 10 illustrated in FIG. 9A. The resist pattern 32 comes to include a stepwise structure substantially the same as that of the template 10.

Alternatively, as illustrated in FIG. 9B, a region of the terrace 121 at each step on a side closer to the thinner region of the stepwise pattern 12 is provided with a projected portion 123 that is projected as compared with the thicker region. For example, the height of the projected portion 123 is determined on the basis of the maximum value of the etching amount at the terraces TR of the resist pattern 32 illustrated in FIGS. 8A and 8B. FIG. 10B illustrates a resist pattern 32 formed by using the template 10 illustrated in FIG. 9B. The resist pattern 32 comes to include a stepwise structure substantially the same as that of the template 10.

Then, an etching process is performed by using the resist pattern 32 illustrated in each of FIGS. 10A and 10B. Consequently, at the time point when the first step of the resist pattern 32 has disappeared, a resist pattern 32 is obtained in which the terrace TR at each step is horizontal as illustrated in FIG. 10C.

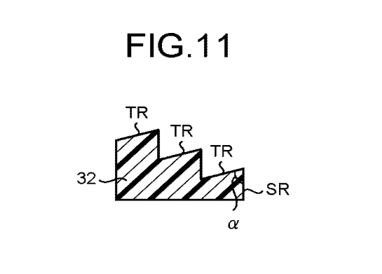

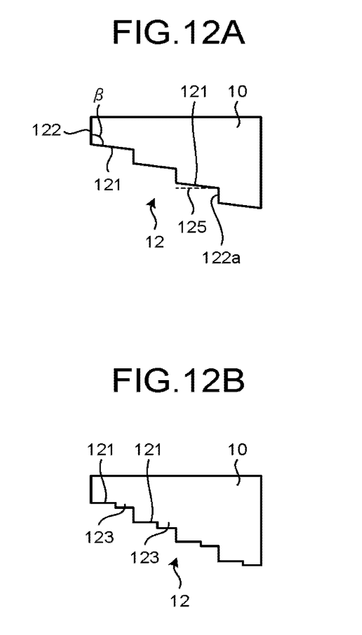

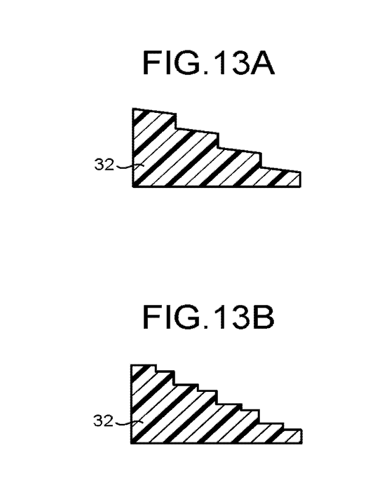

FIG. 11 is a sectional view schematically illustrating another example of a change in the shape of a resist pattern between before and after an etching process according to a comparative example. FIGS. 12A and 12B are partial sectional views schematically illustrating configuration examples of a template according to the third embodiment. FIGS. 13A and 13B are sectional views illustrating examples of a change in the shape of a resist pattern between before and after an etching process, where the resist pattern is formed by the template of each of FIGS. 12A and 12B.

When the stepwise resist pattern 32 including the horizontal terraces TR illustrated in FIG. 8A is used as a mask to etch a processing object, as illustrated in FIG. 11, there is a case where each step of the resist pattern 32 comes to have a shape in which the angle α formed between the terrace TR and the level difference SR becomes an acute angle, when the terrace TR1 at the first step has disappeared. For example, this shape is generated because etched part of the resist pattern 32 is re-deposited on the terraces TR of the resist pattern 32.

In consideration of the above, an etching amount is calculated that is caused by etching at the position of each terrace TR while the terrace TR of one step is disappearing, and the calculated amount is used to correct the shape of the template 10. For example, as illustrated in FIG. 12A, the stepwise pattern 12 of the template 10 is prepared such that the angle β formed between the terrace 121 and the level difference 122 becomes an obtuse angle. Here, in each terrace 121 of the template 10, the difference in the Z-direction between this terrace 121 and a horizontal plane 125 passing through the upper end of the one step-lower level difference 122a is determined on the basis of an etching amount at the position of each terrace TR of the resist pattern 32 illustrated in FIG. 11. Further, the stepwise pattern 12 of the template 10 illustrated in FIG. 12A can be formed by adjusting etching conditions. FIG. 13A illustrates a resist pattern 32 formed by using the template 10 illustrated in FIG. 12A. The resist pattern 32 comes to include a stepwise structure substantially the same as that of the template 10.

Alternatively, as illustrated in FIG. 12B, a region of the terrace 121 at each step on a side closer to the thicker region of the stepwise pattern 12 is provided with a projected portion 123 that is projected as compared with the thinner region. For example, the height of the projected portion 123 is determined on the basis of the maximum value of the etching amount at the terraces TR of the resist pattern 32 illustrated in FIG. 11. FIG. 13B illustrates a resist pattern 32 formed by using the template 10 illustrated in FIG. 12B. The resist pattern 32 comes to include a stepwise structure substantially the same as that of the template 10.

Then, an etching process is performed by using the resist pattern 32 illustrated in each of FIGS. 13A and 13B. Consequently, at the time point when the first step of the resist pattern 32 has disappeared, a resist pattern 32 is obtained in which the terrace TR at each step is horizontal as illustrated in FIG. 10C.

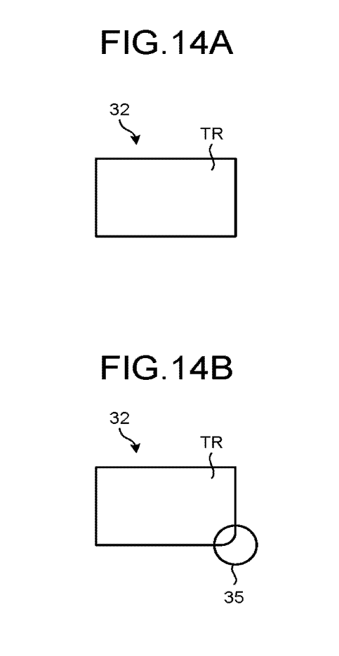

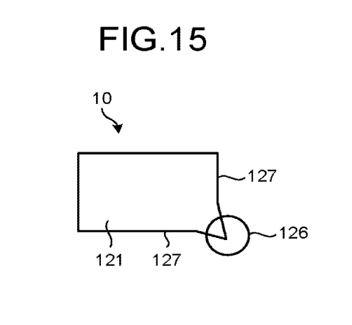

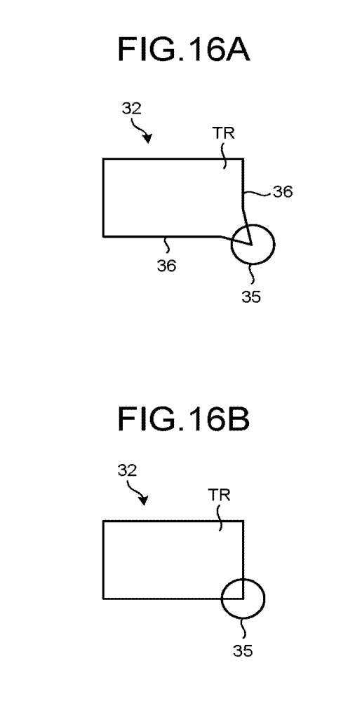

FIGS. 14A and 14B are top views schematically illustrating an example of a change in the shape of a resist pattern between before and after an etching process according to a comparative example. FIG. 15 is a partial top view schematically illustrating a configuration example of a template according to the third embodiment. FIGS. 16A and 16B are top views illustrating an example of a change in the shape of a resist pattern between before and after an etching process, where the resist pattern is formed by the template of FIG. 15.

As illustrated in FIG. 14A, when a template 10 including a stepwise structure with terraces, each of which is rectangular when seen in a plan view, is used to cure a resist, each terrace TR of a stepwise resist pattern 32 becomes rectangular when seen in a plan view. This resist pattern 32 is used as a mask to etch a processing object. As illustrated in FIG. 14B, there is a case where a corner portion 35 of the terrace TR at each step of the resist pattern 32 becomes slimmer, when the terrace TR1 at the first step has disappeared.

In consideration of the above, an etching amount is calculated that is caused by etching at the position of the periphery of each terrace TR while the terrace TR of one step is disappearing, and the calculated amount is used to correct the shape of the template 10. For example, as illustrated in FIG. 15, the stepwise pattern 12 of the template 10 is prepared such that a corner portion 126 of the terrace 121 is set fatter than (or projected from) the periphery 127 defining the terrace 121. FIG. 16A illustrates a resist pattern 32 formed by using the template 10 illustrated in FIG. 15. The resist pattern 32 comes to have a structure in which a corner portion 35 is made fatter than its periphery 36 when seen in a plan view, as in the template 10.

Then, an etching process is performed by using the resist pattern 32 illustrated in FIG. 16A. Consequently, at the time point when the first step of the resist pattern 32 has disappeared, a resist pattern 32 is obtained in which each terrace TR is rectangular when seen in a plan view, as illustrated in FIG. 16B, by suppressing its corner portion 35 from becoming slimmer when seen in a plan view.

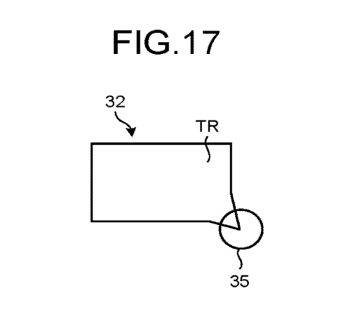

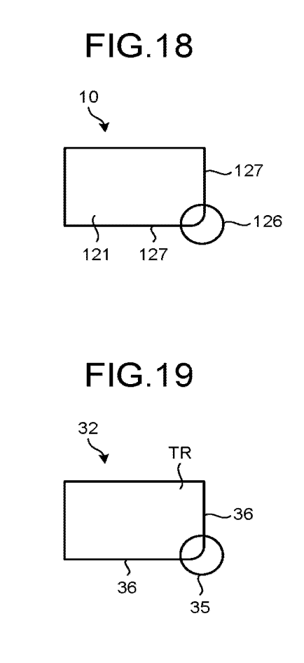

FIG. 17 is a top view schematically illustrating another example of a change in the shape of a resist pattern between before and after an etching process according to a comparative example. FIG. 18 is a partial top view schematically illustrating another configuration example of a template according to the third embodiment. FIG. 19 is a top view illustrating another example of a change in the shape of a resist pattern between before and after an etching process, where the resist pattern is formed by the template of FIG. 18.

As illustrated in FIG. 14A, when a template 10 including a stepwise structure with terraces, each of which is rectangular when seen in a plan view, is used to cure a resist, a stepwise resist pattern 32 is obtained in which each terrace is rectangular when seen in a plan view. This resist pattern 32 is used as a mask to etch a processing object. As illustrated in FIG. 17, there is a case where a corner portion 35 of the terrace TR at each step of the resist pattern 32 becomes fatter (or is projected), when the terrace TR1 at the first step has disappeared.

In consideration of the above, an etching amount is calculated that is caused by etching at the position of the periphery of each terrace TR while the terrace TR of one step is disappearing, and the calculated amount is used to correct the shape of the template 10. For example, as illustrated in FIG. 18, the stepwise pattern 12 of the template 10 is prepared such that a corner portion 126 of the terrace 121 is set slimmer than the periphery 127 defining the terrace 121. FIG. 19 illustrates a resist pattern 32 formed by using the template 10 illustrated in FIG. 18. The resist pattern 32 comes to have a structure in which a corner portion 35 is made slimmer than its periphery 36 when seen in a plan view, as in the template 10.

Then, an etching process is performed by using the resist pattern 32 illustrated in FIG. 19. Consequently, at the time point when the first step of the resist pattern 32 has disappeared, a resist pattern 32 is obtained in which each terrace TR is rectangular when seen in a plan view, as illustrated in FIG. 16B, by suppressing its corner portion 35 from becoming fatter (or being projected) when seen in a plan view.

Also in the third embodiment, an effect substantially the same as that of the first embodiment can be obtained.

### Fourth Embodiment

In the fourth embodiment, an explanation will be given of the sequence of a specific template manufacturing method.

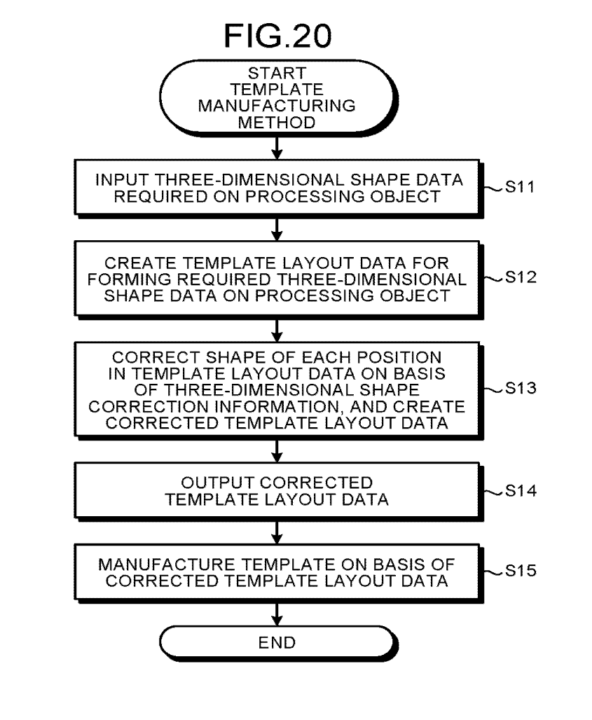

FIG. 20 is a flowchart illustrating an example of the sequence of a template manufacturing method according to a fourth embodiment. Here, the flowchart illustrated in FIG. 20 is executed by an information processing device, for example.

First, three-dimensional shape data containing a stepwise structure required on a processing object is input into the information processing device (step S11). Then, layout data on a template 10 for forming required three-dimensional shape data on the processing object is created in the information processing device (step S12). Here, for example, layout data on a template 10 containing a stepwise structure corresponding to the level difference shape data of step S11 is created, while the depth of each step of the stepwise structure is set.

Then, on the basis of three-dimensional shape correction information, the shape of each position in the layout data on the template 10 is corrected to create corrected layout data on the template 10 (step S13). For example, the three-dimensional shape correction information is a deformation amount per unit height of a resist pattern. For example, the deformation amount is an etching amount on the width of each terrace of the resist pattern. Here, the height of the resist pattern can be translated into the depth of a stepwise structure on the pattern formation face of the template 10.

Thereafter, the corrected layout data on the template 10 is output (step S14). Then, on the basis of the corrected layout data on the template 10, the template 10 is manufactured (step S15). Accordingly, the manufacturing method of the template 10 ends.

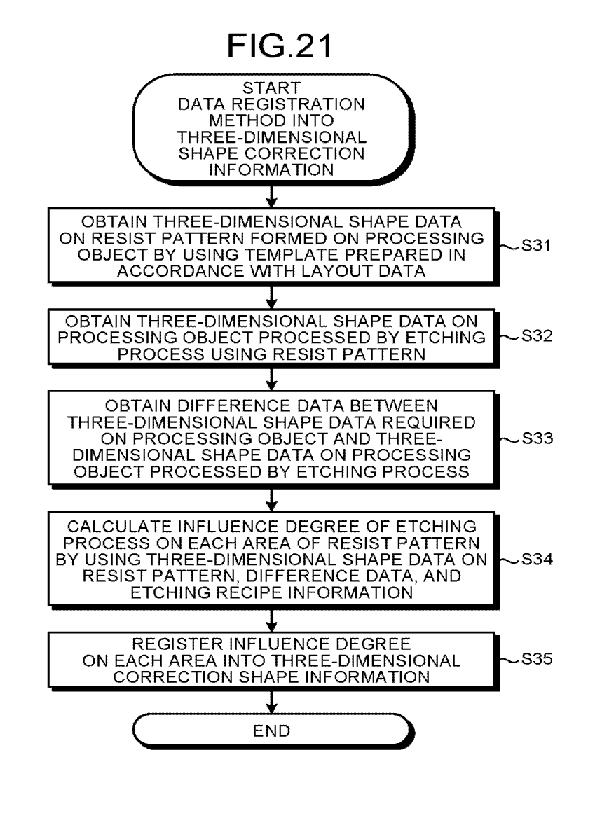

FIG. 21 is a flowchart illustrating an example of the process sequence of a data registration method into three-dimensional shape correction information. First, three-dimensional shape data of a resist pattern that is formed on a processing object by using a prototype template 10 prepared in accordance with the layout data on the template 10 created in step S12 is obtained (step S31). Then, three-dimensional shape data of the processing object to which an etching process, such as the RIE method, has been performed by using this resist pattern is obtained (step S32).

Thereafter, difference data is obtained between the three-dimensional shape data required on a processing object, and the three-dimensional shape data obtained in step S32, which is on the processing object processed by the etching process (step S33). Then, an influence degree of the etching process on each area of the resist pattern is calculated by using the three-dimensional shape data of the resist pattern obtained by step S31, the difference data obtained in step S33, and etching recipe information, such as the etching process time (step S34). As the influence degree on each area, for example, a deformation amount per unit height of the resist pattern may be cited. For example, the deformation amount per unit height of the resist is represented as follows: As described in the first and second embodiments, as the layer of the resist pattern is present more on the upper side, the degree of side etching on the layer becomes larger during an etching process. Further, as described in the third embodiment, the etching situation is different depending on the place.

For example, on the basis of the three-dimensional shape data of the resist pattern and the difference data, it is possible to obtain a deformation amount at each planar position, with respect to the processing object, and a deformation amount at each height, on the resist pattern. It is assumed that the deformation amount at each planar position with respect to the processing object is almost uniform. In this case, a deformation amount per unit height can be obtained by dividing the deformation amount at each height by the height per step of the stepwise structure, for example. Further, the height per step of the stepwise structure can be associated with the etching time in etching recipe information, and more specifically, the etching process time for exposure to the etching process. Accordingly, a deformation amount per unit etching process time can be obtained.

Then, the influence degree on each area is registered into the three-dimensional correction shape information (step S35). The three-dimensional correction shape information contains, for example, correction data concerning how much each step of the resist pattern is to be made fatter or slimmer. Accordingly, the process sequence of the data registration method ends.

Here, the difference data represents the difference between the three-dimensional shape data required on the processing object, and the three-dimensional shape data on the processing object processed by the etching process by using a resist pattern. This resist pattern has been formed by a template for forming the required three-dimensional shape data on the processing object. Accordingly, the difference data comes to contain not only the influence of side etching on the resist pattern during the etching process, but also the influence of side etching on the processing object exposed by removal of the resist pattern.

Here, the process illustrated in FIG. 21 is a process performed by using a prototype template 10, in a case where the number of data to be registered into the three-dimensional correction shape information is small. Specifically, a resist pattern is formed on a processing object by using a prototype template 10 actually created, and then an etching process is performed, so that three-dimensional shape data of the resist pattern and three-dimensional shape data of the processing object processed by the etching process are obtained. Then, the data is registered into the three-dimensional correction shape information. On the other hand, in a case where the number of data to be registered into the three-dimensional correction shape information becomes sufficiently large, the correction process illustrated in FIG. 20 is performed by using data in the three-dimensional correction shape information, without performing an actual working process using a prototype template 10.

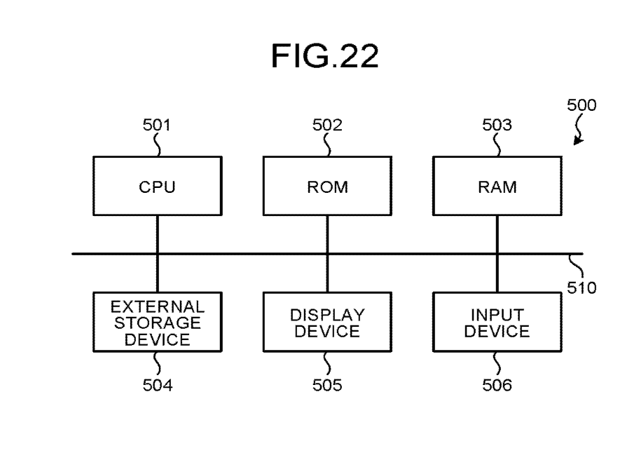

FIG. 22 is a block diagram schematically illustrating a hardware configuration example of an information processing device configured to execute the processes illustrated in FIGS. 20 and 21. The information processing device 500 has a configuration in which a Central Processing Unit (CPU) 501, a Read Only Memory (ROM) 502, a Random Access Memory (RAM) 503, an external storage device 504, such as a Hard Disk Drive (HDD), Solid State Drive (SSD), or Compact Disc (CD) drive device, a display device 505, such as a display, and input devices 506, such as a keyboard and a mouse, are connected to each other via a bus 510.

Each of the manufacturing method of a template 10 and the data registration method into three-dimensional shape correction information, which are described above, is provided as a program. This program is provided in a state recorded in a computer-readable recording medium, such as a CD-ROM, flexible disk (FD), CD-R, Digital Versatile Disk (DVD), or a memory card, by a file in an installable format or executable format.

Alternatively, a program for executing each of the manufacturing method of a template 10 and the data registration method into three-dimensional shape correction information, which are described above, may be provided such that the program is stored in an information processing device connected to a network, such as the internet, and is downloaded via the network. Further, a program for executing each of the manufacturing method of a template 10 and the data registration method into three-dimensional shape correction information, which are described above, may be provided such that the program is provided or distributed via a network, such as the internet.

In the information processing device 500, this program is loaded in the RAM 503 and is executed by the CPU 501, so that the manufacturing method of a template 10 described with reference to FIG. 20 or the data registration method into three-dimensional shape correction information described with reference to FIG. 21 is executed.

In the fourth embodiment, by using the difference data between the three-dimensional shape data required on a processing object and the three-dimensional shape data on a processing object processed by the etching process, the three-dimensional shape data of a stepwise resist pattern, and the etching recipe information, an influence degree of the etching process on each area of the stepwise resist pattern is calculated. Then, on the basis of this influence degree on each area, uncorrected layout data on a template 10 is corrected to obtain corrected shape data on the template 10. Consequently, it is possible to reduce shape errors to be generated when a stepwise resist structure is transferred onto a processing object.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template comprising a first stepwise structure that includes a plurality of first level differences and a plurality of first terraces provided between the first level differences adjacent to each other, the plurality of first level differences being a first to an N-th (N is an integer of 3 or more) provided while being shifted in a first direction, wherein
each of the first terraces includes a second stepwise structure that includes a plurality of second level differences and a plurality of second terraces provided between the second level differences adjacent to each other, the plurality of second level differences being a first to an M-th (M is an integer of 2 or more) provided while being shifted in a second direction perpendicular to the first direction, and
in the plurality of second terraces in each of the first terraces, as a portion dug in the template is deeper, the portion has a larger length in the second direction.

2. The template according to claim 1, wherein one of the second terraces formed at a position dug deepest in each of the first terraces has a length in the second direction, which is larger as a formation position of the first level differences is dug deeper.

3. The template according to claim 2, wherein a difference between a first length and a second length is a predetermined value, the first length being a length in the second direction in one of the second terraces formed at a position dug deepest in a k-th (“k” is an integer of 2 or more and N or less) of the first terraces of the first stepwise structure, the second length being a length in the second direction in one of the second terraces formed at a position dug deepest in a “k−1”-th of the first terraces of the first stepwise structure.

4. The template according to claim 1, wherein a position of a contour at a corner portion of each of the first terraces is present on an outer side than a position of a contour at a corner portion defined by a first side parallel with the first direction and a second side parallel with the second direction, which are provided along an outer shape of this first terrace.

5. The template according to claim 1, wherein a position of a contour at a corner portion of each of the first terraces is present on an inner side than a position of a contour at a corner portion defined by a first side parallel with the first direction and a second side parallel with the second direction, which are provided along an outer shape of this first terrace.

6. A template manufacturing method comprising:
reading first three-dimensional shape data containing a stepwise structure required on a processing object;
generating layout data of a first template including a pattern formation face forming the first three-dimensional shape data;
correcting the layout data by using three-dimensional shape correction information; and
fabricating a second template on a basis of the corrected layout data.

7. The template manufacturing method according to claim 6, wherein the three-dimensional shape correction information includes a deformation amount per unit depth on the pattern formation face.

8. The template manufacturing method according to claim 6, wherein, in the correcting of the layout data, the layout data is corrected to cancel deformation of a second three-dimensional shape data of the processing object processed, the second three-dimensional shape data being obtained by an etching process by using a resist pattern, which has been formed on the processing object by using the first template for the first three-dimensional shape data.

9. The template manufacturing method according to claim 8, wherein, in the correcting of the layout data, the layout data is corrected on a basis of difference data between the first three-dimensional shape data and the second three-dimensional shape data.

10. The template manufacturing method according to claim 8, wherein the correcting of the layout data includes
calculating a deformation amount at each height of the resist pattern, by using three-dimensional shape data of the resist pattern that is formed on the processing object using the first template, and difference data between the first three-dimensional shape data and the second three-dimensional shape data; and
correcting the layout data on a basis of a deformation amount per unit height calculated from the deformation amount at each height.

11. The template manufacturing method according to claim 8, wherein the correcting of the layout data includes
calculating a deformation amount at each area of the resist pattern in an etching process time for exposure to the etching process, by using three-dimensional shape data of the resist pattern that is formed on the processing object using the first template, and difference data between the first three-dimensional shape data and the second three-dimensional shape data; and
correcting the layout data on a basis of a deformation amount per unit etching process time calculated from the deformation amount in the etching process time.

12. The template manufacturing method according to claim 8, wherein the deformation is generated by side etching on the resist pattern, deposition of resist on terraces forming the stepwise structure, or an action of making the resist pattern slimmer or fatter at a corner portion of each of the terraces.

13. The template manufacturing method according to claim 8, wherein
the first three-dimensional shape data includes a first stepwise structure that includes a plurality of first level differences and a plurality of first terraces provided between the first level differences adjacent to each other, the plurality of first level differences being a first to an N-th (N is an integer of 3 or more) provided while being shifted in a first direction, and
in the correcting of the layout data, where a side etching amount in the first direction per step of the resist pattern is denoted by S, a deformation amount per unit height in the first direction becomes S.

14. The template manufacturing method according to claim 13, wherein
each of the first terraces includes a second stepwise structure that includes a plurality of second level differences and a plurality of second terraces provided between the second level differences adjacent to each other, the plurality of second level differences being a first to an M-th (M is an integer of 2 or more) provided while being shifted in a second direction perpendicular to the first direction, and
in the correcting of the layout data, where a side etching amount in the second direction per step of the first stepwise structure of the resist pattern is denoted by R, a deformation amount per unit height in the second direction becomes R.
